(19) United States
(12) Patent Application Publication
(10) Pub. No.: US 2019/0189584 A1
(43) Pub. Date: Jun. 20, 2019

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Fumiyoshi KAWASHIRO, Chiyoda Tokyo (JP)

(21) Appl. No.: 16/120,005

(22) Filed: Aug. 31, 2018

(30) Foreign Application Priority Data
Dec. 20, 2017 (JP) 2017-244341

(51) Int. Cl. H01L 23/00

(52) U.S. Cl. CPC H01L 24/45; H01L 2224/85205; H01L 24/85; H01L 2224/04042; H01L 2224/05082; H01L 2224/05573; H01L 2224/05561; H01L 2224/05166; H01L 2224/05184; H01L 2224/05181; H01L 2224/45147; H01L 2224/45565; H01L 2224/45624; H01L 2224/45639; H01L 2224/45644; H01L 2224/45664; H01L 2224/05124; H01L 24/05

(57) ABSTRACT

According to one embodiment, semiconductor device includes a semiconductor layer, an electrode provided on the semiconductor layer, and a bonding wire connected to the electrode, wherein the electrode comprises a first metal layer containing copper, a second metal layer containing aluminum, provided between the first metal layer and the semiconductor layer, and a third metal layer provided between the first metal layer and the second metal layer, the third metal layer comprising a material different from those of the first metal layer and the second metal layer, and the thickness of the first metal layer is larger than the thickness of the second metal layer and larger than the thickness of the third metal layer.

### CROSS-REFERENCE TO RELATED APPLICATION

This application is based upon and claims the benefit of priority from Japanese Patent Application No. 2017-244341, filed Dec. 20, 2017, the entire contents of which are incorporated herein by reference.

### FIELD

Embodiments described herein relate generally to a semiconductor device and a method for manufacturing the same.

### BACKGROUND

In a power semiconductor module, a bonding wire is used to effect electrical connection between a semiconductor chip and a circuit board or between a semiconductor chip and a power terminal. One end of such a bonding wire is connected to an electrode pad provided in a semiconductor chip.

For saving of energy of devices incorporating power semiconductor modules, higher-density, smaller-sized and higher-temperature operating power semiconductor modules are continually being developed. Thermal stress, applied to the connection between an electrode pad and a bonding wire, increases with the progress toward higher-density, smaller-sized and higher-temperature operating power semiconductor modules. The increase in thermal stress is likely to cause poor reliability, such as an open circuit defect in or with the bonding wire.

### DESCRIPTION OF THE DRAWINGS

FIG. 1 is a schematic cross-sectional view of a semiconductor device according to a first embodiment;

FIG. 2 is an enlarged schematic cross-sectional view of a portion of the first embodiment;

FIG. 3 is a process flow chart of an example of a method for manufacturing the semiconductor device according to the first embodiment;

FIG. 4 is a diagram illustrating the operation and effect of the first embodiment;

FIG. 5 is an enlarged schematic cross-sectional view of a portion of a second embodiment;

FIG. 6 is an enlarged schematic cross-sectional view of a portion of a third embodiment;

FIG. 7 is a diagram illustrating a method for manufacturing the semiconductor device according to the third embodiment;

FIG. 8 is an enlarged schematic cross-sectional view of a portion of a fourth embodiment; and

FIG. 9 is a diagram showing the results of measurement in the Examples.

### DETAILED DESCRIPTION

Embodiments provide a semiconductor device which can have enhanced reliability, and a method for manufacturing the semiconductor device.

In general, according to one embodiment, a semiconductor device includes a semiconductor layer, an electrode provided on the semiconductor layer, and a bonding wire connected to the electrode, wherein the electrode comprises a first metal layer containing copper, a second metal layer containing aluminum, provided between the first metal layer and the semiconductor layer, and a third metal layer provided between the first metal layer and the second metal layer, the third metal layer comprising a material different from those of the first metal layer and the second metal layer, and the thickness of the first metal layer is larger than the thickness of the second metal layer and larger than the thickness of the third metal layer.

In the following description, the same reference numerals are used for the same or similar members, and a duplicate description thereof may be omitted.

In the following description, an upward direction and a downward direction in the drawings may sometimes be described in such terms as “above” and “below” to indicate a positional relationship e.g. between components. As used herein, such terms as “above” and “below” do not always refer to the corresponding positional concept in the gravitational direction.

### First Embodiment

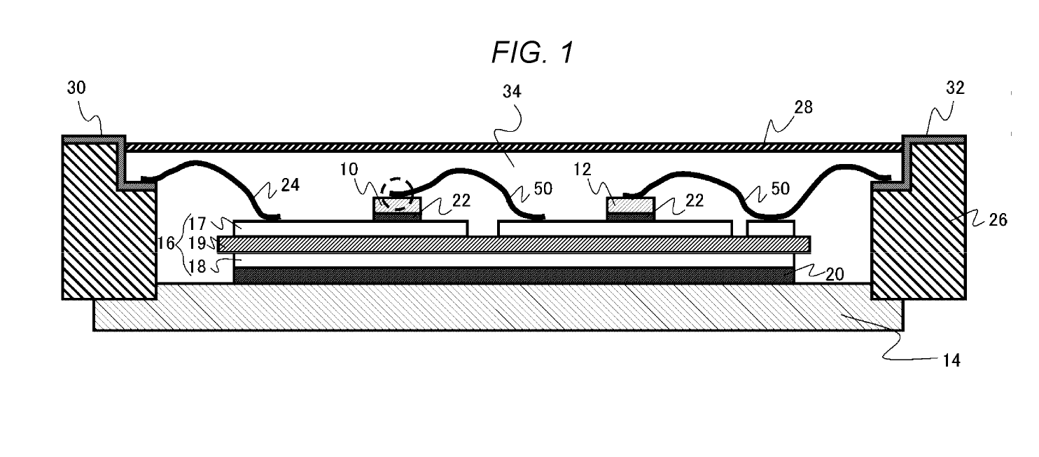

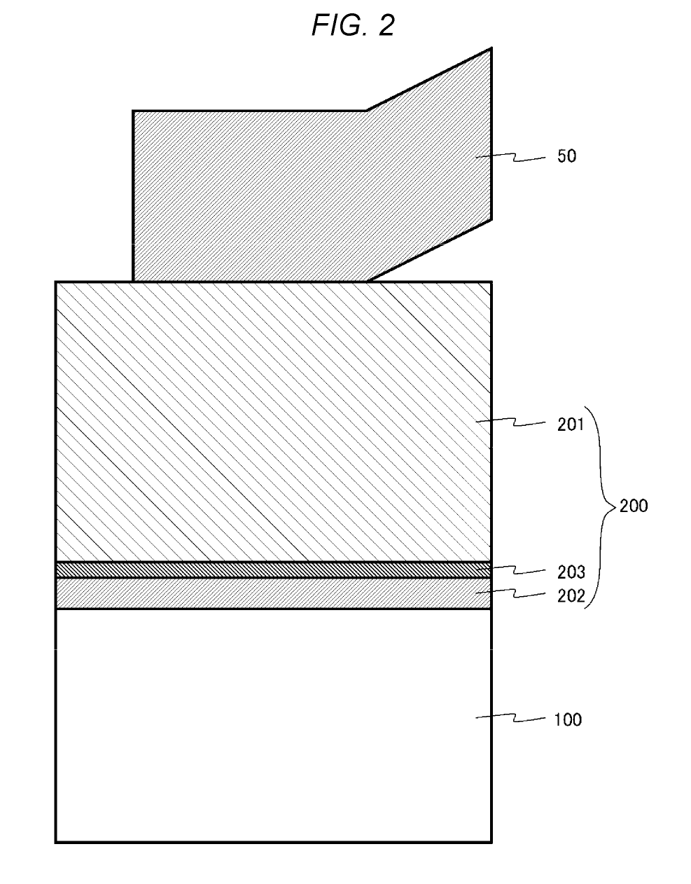

FIG. 1 is a schematic cross-sectional view of the semiconductor device according to the first embodiment. FIG. 2 is an enlarged schematic cross-sectional view of a portion of the first embodiment. FIG. 2 is an enlarged view of the area enclosed by the dotted circle in FIG. 1. The semiconductor device of the first embodiment is a power semiconductor module. SBDs (Schottky Barrier Diodes) are mounted in the power semiconductor module.

The power semiconductor module of the first embodiment includes an SBD 10 (semiconductor chip), an SBD 12, a base plate 14, an insulating circuit board 16, a first solder layer 20, a second solder layer 22, a resin case 26, a cover 28, a first power terminal 30, a second power terminal 32, a silicone gel 34, and bonding wires 50. The insulating circuit board 16 has a first conductive layer 17, a second conductive layer 18, and a ceramic layer 19.

The SBDs 10, 12 (semiconductor chips) have a semiconductor layer 100 such as a portion of a semiconductor substrate or a layer thereon and an electrode pad 200 (electrode). The electrode pad 200 has an OPM (Over Pad Metallization) layer 201 (first metal layer), a pad layer 202 (second metal layer), and a barrier metal layer 203 (third metal layer).

The SBD 10 and the SBD 12 are provided on the insulating circuit board 16. The SBD 10 and the SBD 12 are high-voltage SBDs having a breakdown voltage of, for example, 600 V or more. The SBD 10 and the SBD 12 are each secured to the first conductive layer 17 by the second solder layer 22. The second solder layer 22 is made of a die mount material. A material having a higher thermal conductivity than solder, such as a sintered Ag material or a sintered Cu material, may be used as the die mount material. The SBD 10 and the SBD 12 are SBDs using, for example, silicon (Si) or silicon carbide (SiC).

The base plate 14 is made of, for example, a metal containing copper. The base plate 14 is made of, for example, pure copper or a copper alloy. Alternatively, the base plate 14 may be made of aluminum. Alternatively, the base plate 14 may be made of a composite material composed of a highly thermally conductive ceramic material and a metal, for example, a composite material composed of silicon carbide and aluminum.

The insulating circuit board 16 is provided between the SBD 10 and the base plate 14, and between the SBD 12 and the base plate 14. The insulating circuit board 16 functions to ensure electrical insulation between the SBD 10 and the base plate 14, and between the SBD 12 and the base plate 14. The first solder layer 20 is provided between the base plate 14 and the insulating circuit board 16.

The insulating circuit board 16 has the first conductive layer 17, the second conductive layer 18, and the ceramic layer 19. The first conductive layer 17 and the second conductive layer 18 are, for example, metal films. The first conductive layer 17 and the second conductive layer 18 contain, for example, copper. The first conductive layer 17 and the second conductive layer 18 are made of, for example, pure copper. The ceramic layer 19 is made of, for example, aluminum oxide, silicon nitride or aluminum nitride.

The first solder layer 20 is provided between the second conductive layer 18 and the base plate 14. The first solder layer 20 secures the insulating circuit board 16 to the base plate 14.

The resin case 26 is provided such that it surrounds the circumference of the insulating circuit board 16. The cover 28, which is made of a resin, is provided on the resin case 26. The insulating circuit board 16 lies between the cover 28 and the base plate 14.

The interior of the power semiconductor module is filled with the silicone gel 34 as a sealant. The resin case 26, the base plate 14, the cover 28 and the silicone gel 34 function to protect or insulate the members within the power semiconductor module. A usable sealant material is not limited to a silicone gel; for example, an epoxy molding resin may be used.

The first power terminal 30 and the second power terminal 32 are provided at the top of the resin case 26. For example, the first power terminal 30 is an N-terminal, and the second power terminal 32 is a P-terminal. A not-shown AC output terminal and a not-shown gate terminal, for example, are provided at the top of the resin case 26. Electrical connections between the power semiconductor module and the outside are effected through these terminals.

The first power terminal 30 is electrically connected to the first conductive layer 17 by means of a bonding wire 50. The SBD 10 is electrically connected to the first conductive layer 17 by means of a bonding wire 50. The SBD 12 is electrically connected to the first conductive layer 17 by means of a bonding wire 50. The first conductive layer 17 is electrically connected to the second power terminal 32 by means of the bonding wire 50. The first power terminal 30 may be bonded to the first conductive layer 17 by means of solder without using a bonding wire, or may be directly bonded to the first conductive layer 17 by using, for example, ultrasonic bonding.

The semiconductor layer 100 is made of, for example, monocrystalline silicon or monocrystalline silicon carbide. The semiconductor layer 100 is, for example, an n-type semiconductor.

The electrode pad 200 is provided on the semiconductor layer 100. The electrode pad 200 is provided in contact with the semiconductor layer 100. The electrode pad 200 is, for example, an anode electrode of the SBD.

The electrode pad 200 has the OPM layer 201, the pad layer 202, and the barrier metal layer 203. These layers are arranged in the order of the pad layer 202, the barrier metal layer 203 and the OPM layer 201, with the pad layer 202 being closest to the semiconductor layer 100.

The OPM layer 201 contains copper (Cu). The material of the OPM layer 201 is a metal containing copper. The main-component element of the OPM layer 201 is copper. The term “main-component element” herein refers to a component element whose content in a layer is the greatest of all the component elements of a material.

The material of the OPM layer 201 is, for example, pure copper or a copper alloy. The OPM layer 201 is made of, for example, a copper alloy containing copper (Cu) and at least one metal element selected from the group consisting of silver (Ag), nickel (Ni), iron (Fe), zinc (Zn), tin (Sn), chromium (Cr), and tungsten (W).

The thickness of the OPM layer 201 is larger than the thickness of the pad layer 202. The thickness of the OPM layer 201 is larger than the thickness of the barrier metal layer 203. The thickness of the OPM layer 201 is, for example, equal to or more than 20 μm and equal to or less than 300 μm. The thickness of the OPM layer 201 is, for example, at least 5 times the thickness of the pad layer 202.

The OPM layer 201 reduces thermal stress caused by a difference in linear expansion coefficient between the semiconductor layer 100 and the bonding wire 50. Thus, the OPM layer 201 functions to enhance the reliability of the connection between the electrode pad 200 and the bonding wire 50. Further, the OPM layer 201 functions to reduce mechanical shock applied to the semiconductor layer 100 and the pad layer 202 upon connection thereof to the bonding wire 50.

The pad layer 202 is provided between the OPM layer 201 and the semiconductor layer 100. The material of the pad layer 202 is a metal containing aluminum (Al). The main-component element of the pad layer 202 is aluminum.

The material of the pad layer 202 is, for example, pure aluminum or an aluminum alloy. The material of the pad layer 202 is, for example, an aluminum alloy containing aluminum and silicon (Si) or copper (Cu).

The thickness of the pad layer 202 is, for example, equal to or more than 1 μm and equal to or less than 10 μm.

The pad layer 202 functions to electrically connect the semiconductor layer 100 and the bonding wire 50.

The barrier metal layer 203 is provided between the OPM layer 201 and the pad layer 202. The barrier metal layer 203 is made of, for example, a metal containing at least one metal element selected from the group consisting of titanium (Ti), tungsten (W), and tantalum (Ta).

The material of the barrier metal layer 203 contains, for example, at least one material selected from the group consisting of titanium, tungsten, tantalum, titanium nitride, tungsten nitride, tantalum nitride, and a titanium/tungsten alloy. A metal nitride is categorized herein as a metal.

The thickness of the barrier metal layer 203 is smaller than the thickness of the pad layer 202. The thickness of the barrier metal layer 203 is, for example, equal to or more 0.01 μm and equal to or less than 0.2 μm.

The barrier metal layer 203 functions to inhibit reaction between the material of the OPM layer 201 and the material of the pad layer 202, thereby inhibiting the formation of an intermetallic compound thereof.

The bonding wire 50 is connected to the electrode pad 200. The bonding wire 50 is made of, for example, a metal containing at least one metal element selected from the group consisting of aluminum (Al), copper (Cu), silver (Ag), and gold (Au). The main-component element of the bonding wire 50 is, for example, aluminum (Al), copper (Cu), silver (Ag), or gold (Au).

The material of the bonding wire 50 is, for example, pure aluminum or an aluminum alloy. Alternatively, the material of the bonding wire 50 is, for example, pure copper or a copper alloy.

The bonding wire 50 has a cylindrical shape or a flat ribbon-like shape. The width of the bonding wire 50 is, for example, equal to or more than 100 μm and equal to or less than 600 μm. The width of the bonding wire 50 is defined as the maximum width in a cross section perpendicular to the extension direction of the bonding wire 50.

A not-shown intermetallic compound may exist between the bonding wire 50 and the electrode pad 200. It is possible that an intermetallic compound may be formed through reaction between the material of the bonding wire 50 and the material of the electrode pad 200.

A method for manufacturing the semiconductor device of the first embodiment will now be described. The method for manufacturing the semiconductor device of the first embodiment comprises forming a first metal layer containing copper over a semiconductor layer by an ionized metal plasma processing (also referred to herein as “ion plating”), and connecting a bonding wire onto the first metal layer.

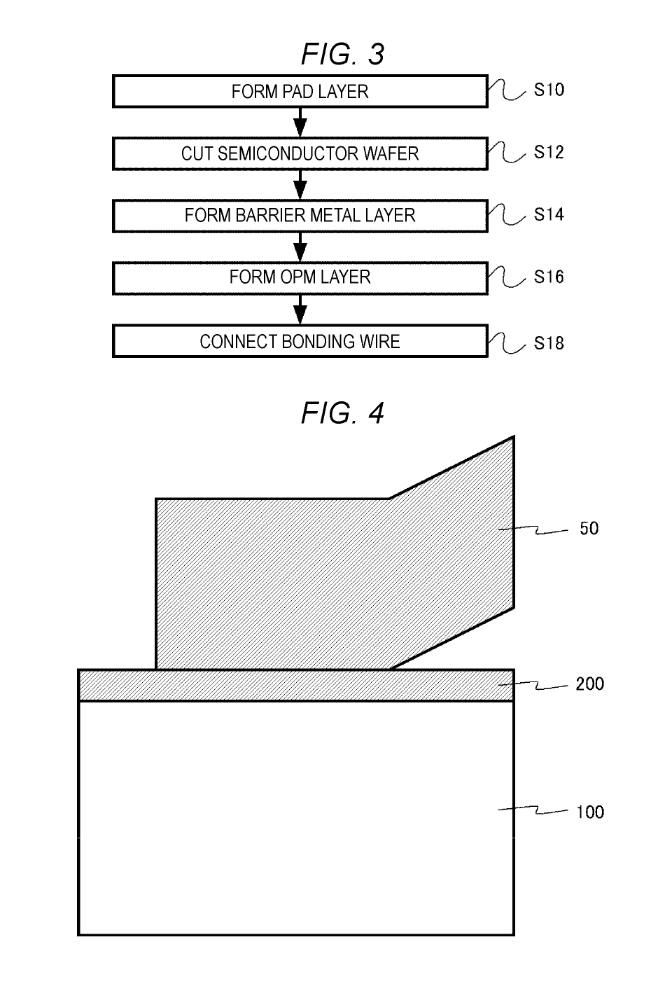

FIG. 3 is a process flow chart of an example of the method for manufacturing the semiconductor device of the first embodiment.

First, a semiconductor wafer (semiconductor substrate) is prepared. Next, a pad layer 202 is formed on the semiconductor layer 100 of the semiconductor wafer (S10). For example, the pad layer 202 is formed by depositing an aluminum film on the semiconductor layer 100 by sputtering it thereon. A number of SBDs (semiconductor chips) are formed on the semiconductor wafer.

Next, device characteristics of the SBDs on the semiconductor wafer are evaluated to determine good and defective products.

Next, the semiconductor wafer is cut or singulated into individual SBDs (S12). The cutting of the semiconductor wafer is performed, for example, by blade dicing.

Next, the SBD's are tested and only good SBD's, e.g., good products, are selected from among the individual SBDs. A barrier metal layer 203 is formed on the pad layer 202 of a good product SBD (S14). For example, a titanium film is deposited on the pad layer 202 by sputtering it thereon.

Next, an OPM layer 201 is formed on the barrier metal layer 203 of the SBD (S16). The OPM layer 201 is formed by ion plating. For example, a copper film is deposited on the barrier metal layer 203 by ion plating.

Next, the SBD is placed on an insulating circuit board 16. The SBD is bonded to the insulating circuit board 16, for example, by soldering. Thereafter, a resin case 26 is mounted around the insulating circuit board 16.

Next, a bonding wire 50 is connected onto the electrode pad 200 (S18). The bonding wire 50 is connected to the surface of the OPM layer 201. The connection of the bonding wire 50 to the electrode pad 200 is performed by pressing the bonding wire 50 against the surface of the OPM layer 201 with a predetermined load while applying ultrasonic vibration thereto.

Thereafter, the SBDs 10, 12, the bonding wire 50, etc. in the resin case 26 are sealed with a sealant, and a cover 28 is mounted e.g. with an adhesive. The sealant is, for example, a silicone gel 34.

The power semiconductor module of the first embodiment is manufactured by the above-described manufacturing method.

A description will now be given of the operation and effect of the semiconductor device according to the first embodiment and the manufacturing method for the semiconductor device.

For saving of energy of devices incorporating power semiconductor modules, higher-density, smaller-sized and higher-temperature operating power semiconductor modules are continually being developed. Thermal stress, applied to the connection between an electrode pad and a bonding wire, increases with the progress toward higher-density, smaller-sized and higher-temperature operating power semiconductor modules. The increase in thermal stress is likely to cause poor reliability, such as an open circuit defect in or with the bonding wire.

The thermal stress applied to the connection between an electrode pad and a bonding wire is generated due to a difference in linear expansion coefficient between the material of a semiconductor layer and the material of the bonding wire. In general, the linear expansion coefficient of the metal of a bonding wire is higher than the linear expansion coefficient of the semiconductor of a semiconductor layer.

A large difference in linear expansion coefficient between the two materials will cause, for example, generation of heat from the semiconductor chip, resulting in the application of high shear stress to the connection portion of the bonding wire. This may cause cracking in the bonding wire, leading to an open circuit defect in or with the bonding wire.

To provide a high-temperature operating power semiconductor module, silicon carbide, which has higher heat resistance than silicon, is sometimes used as a semiconductor layer material. The linear expansion coefficient of silicon carbide is approximately equal to that of silicon. However, a silicon carbide semiconductor layer is generally thicker than a silicon semiconductor layer. Therefore, there is a larger difference in apparent linear expansion coefficient between the material of a silicon carbide semiconductor layer and the metal of a bonding wire. Accordingly, compared to the case of a silicon semiconductor layer, higher thermal stress will be applied to the connection between the electrode pad and the bonding wire. Thus, the use of silicon carbide entails a higher demand for the reliability of a bonding wire.

FIG. 4 is a diagram illustrating the operation and effect of the first embodiment. FIG. 4 is a schematic enlarged cross-sectional view of a portion of a comparative semiconductor device. The comparative semiconductor device is a power semiconductor module. FIG. 4 is a diagram corresponding to FIG. 2 illustrating the first embodiment.

The comparative power semiconductor module differs from the first embodiment in that the electrode pad 200 consists of a single pad layer, i.e. the electrode pad 200 does not include an OPM layer nor a barrier metal layer.

When the bonding wire 50 is connected to a thin electrode pad 200 as in the comparative power semiconductor module, the distance between the bonding wire 50 and the semiconductor layer 100 is small. Therefore, high shear stress is applied to the connection portion of the bonding wire 50, which is likely to cause poor reliability of the bonding wire 50 or the connection.

Further, because of the small thickness of the electrode pad 200, a large mechanical shock will be applied to the electrode pad 200 and the semiconductor layer 100 upon connection to the bonding wire 50, which can cause damage to the electrode pad 200 and the semiconductor layer 100.

In the power semiconductor module of the first embodiment, the OPM layer 201, which is thicker than the pad layer 202, is provided between the bonding wire 50 and the pad layer 202. Therefore, the distance between the bonding wire 50 and the semiconductor layer 100 is larger than that of the comparative semiconductor device. Accordingly, lower shear stress will be applied to the connection portion of the bonding wire 50. This enhances the reliability of the power semiconductor module.

Further, because of the thicker electrode pad 200 than the comparative one, a smaller mechanical shock will be applied to the electrode pad 200 and the semiconductor layer 100 upon connection to the bonding wire 50. This reduces the possibility of damage to the electrode pad 200 and the semiconductor layer 100.

In the power semiconductor module of the first embodiment, the OPM layer 201 contains copper, and the pad layer 202 contains aluminum. Therefore, if the OPM layer 201 and the pad layer 202 are in contact with each other, then it is possible that the material of the OPM layer 201 may react with the material of the pad layer 202, thereby forming an intermetallic compound of copper and aluminum between the OPM layer 201 and the pad layer 202.

Some intermetallic compounds of copper and aluminum, such as Cu₉Al₄ and Cu₃Al₂, have low corrosion resistance to halogens and sulfur, and can possibly reduce the reliability of the electrode pad 200. For example, it is possible that an intermetallic compound formed by these materials will be corroded by a halogen contained in the sealant, resulting in reduced reliability of the power semiconductor module.

In the power semiconductor module of the first embodiment, the barrier metal layer 203 is provided between the OPM layer 201 and the pad layer 202. The barrier metal layer 203 inhibits reaction between the material of the OPM layer 201 and the material of the pad layer 202, thereby inhibiting the formation of an intermetallic compound of copper and aluminum. This enhances the corrosion resistance of the electrode pad 200, thus enhancing the reliability of the power semiconductor module.

In the manufacturing method for the power semiconductor module of the first embodiment, ion plating is used to form the OPM layer 201. In this context, ion plating refers to a process including generating a plasma in a reaction chamber to ionize and positively charge metal particles as a film material. Ion plating may also be referred to as ionized metal plasma deposition or processing. The positively charged metal particles are attracted to a negatively charged substrate, and are thus deposited on the substrate. Compared to other film forming methods such as sputtering, vapor deposition and plating, ion plating can stably form a thick film with high adhesion to the substrate.

Therefore, the use of ionized metal plasmas for the formation of the OPM layer 201 enhances the reliability of the power semiconductor module and, in addition, increases the productivity.

In the manufacturing method for the power semiconductor module of the first embodiment, after the determination of good and defective semiconductor chip products, the OPM layer 201 is formed only on good semiconductor chips. This reduces the production cost of the power semiconductor module. Further, this facilitates inhibition of surface oxidation of the OPM layer 201, for example, in a semiconductor wafer cutting process.

Ion plating can easily form a thick film on a singulated semiconductor chip. This facilitates the formation of the OPM layer 201 only on good semiconductor chips after the determination of good and defective semiconductor chip products has been completed.

The thickness of the OPM layer 201 is preferably equal to or more than 20 μm and equal to or less than 300 μm, more preferably equal to or more than 30 μm and equal to or less than 200 μm, still more preferably equal to or more than 40 μm and equal to or less than 100 μm. If the thickness is lower than the above range, the shear stress, applied to the connection portion of the bonding wire 50, may not be sufficiently low. Further, the mechanical shock, applied to the electrode pad 200 and the semiconductor layer 100, may not be sufficiently small. If the thickness exceeds the above range, it may take a longer time to form the OPM layer 201, resulting in an increased production cost.

The OPM layer 201 is preferably made of a copper alloy containing copper (Cu) and at least one metal element selected from the group consisting of silver (Ag), nickel (Ni), iron (Fe), zinc (Zn), tin (Sn), chromium (Cr), and tungsten (W). Compared to the use of pure copper, the use of such a copper alloy is expected to increase the upper temperature limit and the mechanical strength of the OPM layer 201, thereby enhancing the reliability during operation at high temperatures.

From the viewpoint of inhibiting reaction between the material of the OPM layer 201 and the material of the pad layer 202, the barrier metal layer 203 preferably contains at least one metal element selected from the group consisting of titanium, tungsten and tantalum. From the same viewpoint, the material of the barrier metal layer 203 preferably contains at least one material selected from the group consisting of titanium, tungsten, tantalum, titanium nitride, tungsten nitride, tantalum nitride, and a titanium/tungsten alloy.

The bonding wire 50 preferably contains copper. Pure copper or a copper alloy is a preferable material for the bonding wire 50. For example, copper has a higher thermal conductivity than aluminum. Therefore, the use of a copper-containing material reduces the rise in the temperature of the connection portion of the bonding wire 50. Accordingly, lower shear stress will be applied to the connection portion of the bonding wire 50. This enhances the reliability of the power semiconductor module.

The width of the bonding wire 50 is preferably equal to or more than 100 μm and equal to or less than 600 μm. If the width is lower than the above range, there is a fear of fusing, i.e., melting through, of the bonding wire 50 due to insufficient current-carrying capacity in the wire. If the width is higher than the above range, connection of the bonding wire 50 to the electrode pad 200 can be difficult.

As described hereinabove, according to the first embodiment, lowering of the reliability of the connection portion of the bonding wire 50 and the reliability of the electrode pad 200 is prevented, and a power semiconductor module with enhanced reliability and a manufacturing method for the module are achieved.

### Second Embodiment

A semiconductor device according to a second embodiment includes a semiconductor layer; an electrode provided on the semiconductor layer, the electrode comprising a first metal layer containing copper, and a bonding wire connected to the electrode, the bonding wire comprising a core layer containing copper, and a cover layer covering the core layer.

The semiconductor device of the second embodiment differs from that of the first embodiment in that the bonding wire has a core layer containing copper and a cover layer covering the core layer. The same description as given above with reference to the first embodiment will be omitted.

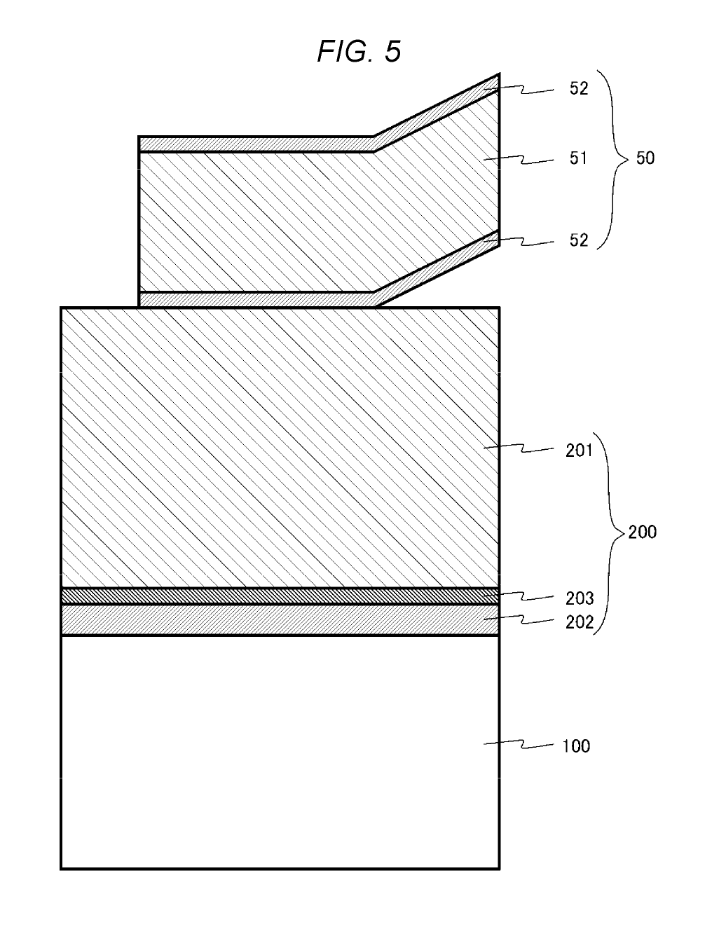

FIG. 5 is an enlarged schematic cross-sectional view of a portion of the second embodiment. FIG. 5 is a diagram corresponding to FIG. 2 illustrating the first embodiment.

The OPM layer 201 contains copper (Cu). The material of the OPM layer 201 is a metal containing copper. The main-component element of the OPM layer 201 is copper.

The bonding wire 50 has a core layer 51, and a cover layer 52 covering the core layer 51. The cover layer 52 is in contact with the OPM layer 201 of the electrode pad 200.

The core layer 51 contains copper. The main-component element of the core layer 51 is copper. The material of the core layer 51 is, for example, pure copper or a copper alloy.

The cover layer 52 is made of, for example, a metal containing at least one metal element selected from the group consisting of aluminum, silver, gold, and palladium. The material of the cover layer 52 is, for example, aluminum or silver. The material of the cover layer 52 is, for example, a material having higher oxidation resistance than the core layer 51.

If the cover layer 52 is absent, the bonding wire 50 containing copper will have poor oxidation resistance. Thus, for example, oxidation will progress even in the atmospheric environment, which makes management of the bonding wire 50 difficult.

The bonding wire 50 of the second embodiment has the cover layer 52, which has high oxidation resistance, around the copper-containing core layer 51. Since oxidation of the copper-containing core layer 51 is inhibited, the bonding wire 50 can be managed with ease. This increases the productivity of the power semiconductor module.

The material of the cover layer 52 is preferably silver. If reaction occurs between silver contained in the cover layer 52 and copper contained in the OPM layer 201, no intermetallic compound having poor corrosion resistance will be formed. This enhances the reliability of the power semiconductor module.

Thus, according to the second embodiment, in addition to the operation and effect of the first embodiment, a power semiconductor module with increased productivity is achieved.

### Third Embodiment

A semiconductor device according to a third embodiment differs from the second embodiment in that the first metal layer is in contact with the core layer. The same description as given above with reference to the second embodiment will be omitted.

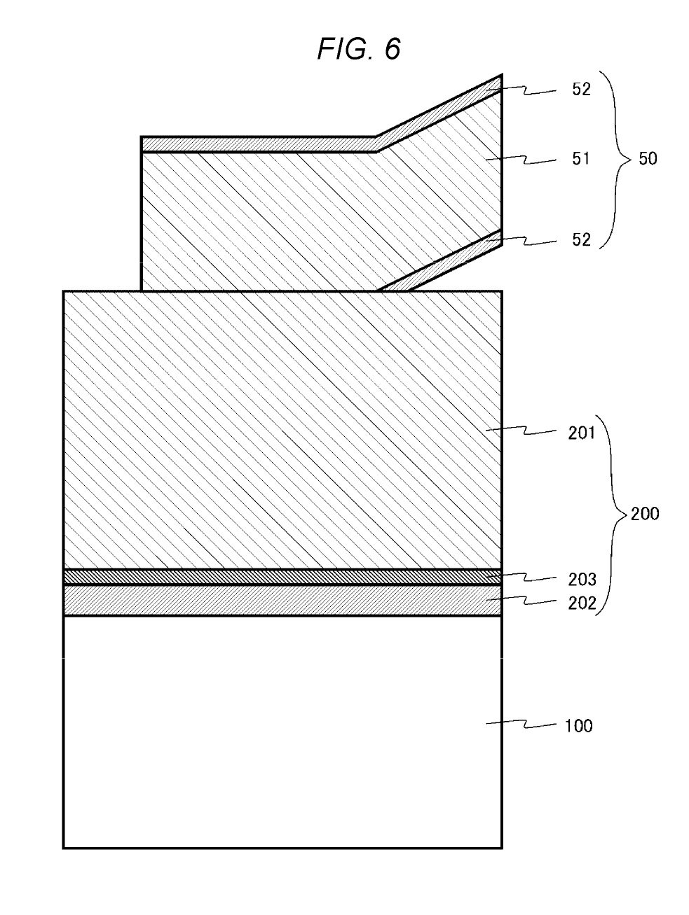

FIG. 6 is an enlarged schematic cross-sectional view of a portion of the third embodiment. FIG. 6 is a diagram corresponding to FIG. 2 illustrating the first embodiment.

The OPM layer 201 contains copper (Cu). The material of the OPM layer 201 is a metal containing copper. The main-component element of the OPM layer 201 is copper. In one example, the OPM layer 201 does not contain aluminum.

The bonding wire 50 has a core layer 51, and a cover layer 52 covering the core layer 51. The core layer 51 is in contact with the OPM layer 201 (first metal layer) of the electrode pad 200.

The core layer 51 contains copper. The main-component element of the core layer 51 is copper. The material of the core layer 51 is, for example, pure copper or a copper alloy. In one example, the core layer 51 does not contain aluminum.

The cover layer 52 is made of, for example, a metal containing at least one metal element selected from the group consisting of aluminum, silver, gold, and palladium. The material of the cover layer 52 is, for example, aluminum or silver. The material of the cover layer 52 is, for example, a material having higher oxidation resistance than the core layer 51.

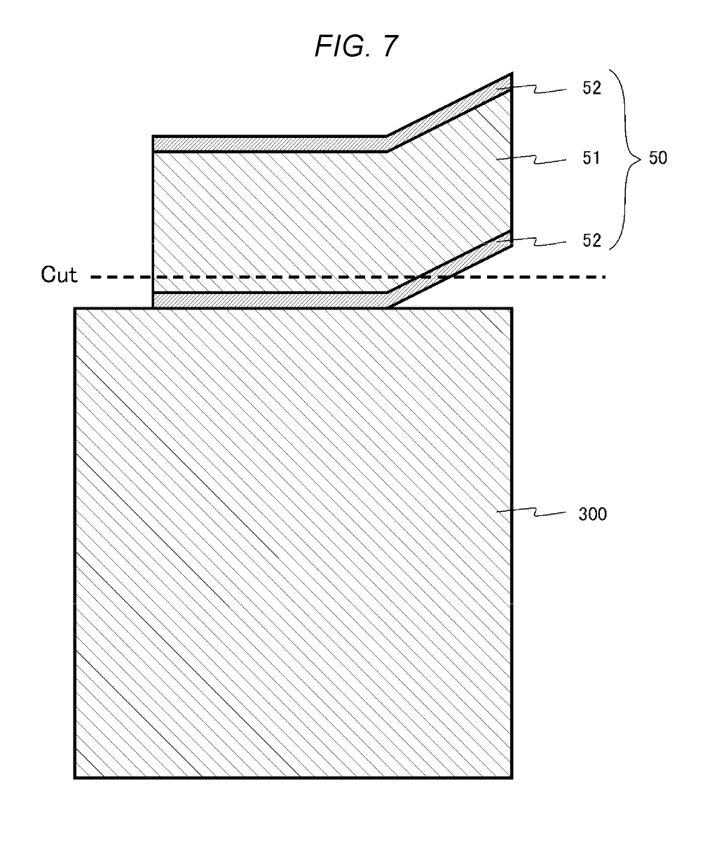

FIG. 7 is a diagram illustrating a method for manufacturing the semiconductor device according to the third embodiment.

For example, before connecting the bonding wire 50 to the electrode pad 200, the bonding wire 50 is provisionally connected onto the aluminum surface of a provisional connecting portion 300 of a wire bonder. A bottom portion (the broken-line portion shown in FIG. 7) of the bonding wire 50 is then cut off e.g. with a cutter.

Consequently, the core layer 51 becomes exposed at the bottom of the bonding wire 50. Thereafter, the exposed core layer 51 is connected to the surface of the OPM layer 201 of the electrode pad 200. Thus, the exposed core layer 51 is brought into contact with the surface of the OPM layer 201.

By allowing the copper-containing core layer 51 to be in contact with the copper-containing OPM layer 201, no intermetallic compound having poor corrosion resistance will be formed between the core layer 51 and the OPM layer 201. This enhances the reliability of the power semiconductor module.

Further, by allowing the copper-containing core layer 51 to be in contact with the copper-containing OPM layer 201, the linear expansion coefficient of the connection between the bonding wire 50 and the electrode pad 200 can be made uniform, e.g., the same. This reduces the thermal stress applied to the connection, thereby enhancing the reliability of the power semiconductor module.

Thus, according to the third embodiment, in addition to the operation and effect of the second embodiment, a power semiconductor module with more enhanced reliability is achieved.

### Fourth Embodiment

A semiconductor device according to a fourth embodiment differs from the second embodiment in that the electrode has a fourth metal layer, which is made of the same material as the cover layer, between the first metal layer and the bonding wire, and that the cover layer and the fourth metal layer are in contact with each other. The same description as given above with reference to the second embodiment will be omitted.

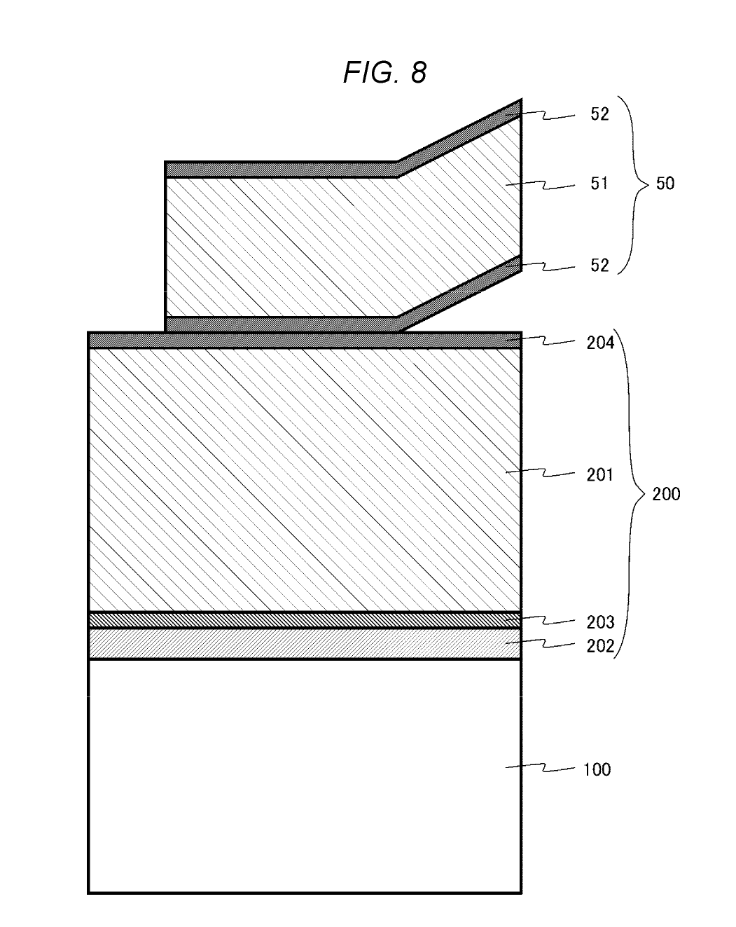

FIG. 8 is an enlarged schematic cross-sectional view of a portion of the fourth embodiment. FIG. 8 is a diagram corresponding to FIG. 2 illustrating the first embodiment.

The bonding wire 50 has a core layer 51, and a cover layer 52 covering the core layer 51. The cover layer 52 is in contact with a surface layer 204 of the electrode pad 200.

The core layer 51 contains copper. The main-component element of the core layer 51 is copper. The material of the core layer 51 is, for example, pure copper or a copper alloy.

The cover layer 52 is made of, for example, a metal containing at least one metal element selected from the group consisting of aluminum, silver, gold, and palladium. The material of the cover layer 52 is, for example, aluminum or silver. The material of the cover layer 52 is, for example, a material having higher oxidation resistance than the core layer 51.

The electrode pad 200 has an OPM layer 201 (first metal layer), a pad layer 202, a barrier metal layer 203, and a surface layer 204 (fourth metal layer). These layers are arranged in the order of the pad layer 202, the barrier metal layer 203, the OPM layer 201 and the surface layer 204, with the pad layer 202 being closest to the semiconductor layer 100.

The OPM layer 201 contains copper (Cu). The material of the OPM layer 201 is a metal containing copper. The main-component element of the OPM layer 201 is copper.

The material of the surface layer 204 is the same as the material of the cover layer 52. The surface layer 204 is made of, for example, a metal containing at least one metal element selected from the group consisting of aluminum, silver, gold, and palladium. The material of the surface layer 204 is, for example, aluminum or silver.

The thickness of the surface layer 204 is, for example, equal to or more than 0.1 μm and equal to or less than 10 μm.

The cover layer 52 can be partly or wholly destroyed by an ultrasonic vibration applied upon connection of the bonding wire 50 to the electrode pad 200. If, in such a case, the surface layer 204 is absent and the material of the OPM layer 201 is different from the material of the cover layer 52, the material structure of the connection between the bonding wire 50 and the electrode pad 200 will be non-uniform.

In the fourth embodiment, the surface layer 204 and the cover layer 52 are made of the same material. Accordingly, even when the cover layer 52 is partly or wholly destroyed, the surface layer 204 remains and the material structure of the connection between the bonding wire 50 and the electrode pad 200 remains uniform. This leads to, for example, a uniform distribution of thermal stress, resulting in enhanced reliability of the power semiconductor module.

The material of the surface layer 204 and the cover layer 52 is preferably silver. If reaction occurs between silver contained in the surface layer 204 and the cover layer 52 and copper contained in the OPM layer 201, no intermetallic compound having poor corrosion resistance will be formed. This enhances the reliability of the power semiconductor module.

Thus, according to the fourth embodiment, in addition to the operation and effect of the second embodiment, a power semiconductor module with more enhanced reliability is achieved.

### EXAMPLES

### Example 1

A power semiconductor module having the same structure as the first embodiment was produced. Each semiconductor chip was an SBD having a semiconductor layer 100 of silicon carbide.

The electrode pad 200 has an OPM layer 201 (first metal layer), a pad layer 202 and a barrier metal layer 203. The OPM layer 201 was a pure copper film having a thickness of 25 μm, the pad layer 202 was a pure aluminum film having a thickness of 4 μm, and the barrier metal layer 203 was a pure titanium film having a thickness of 0.1 μm. The copper film of the OPM layer 201 was formed from ionized metal plasma (ion plating).

The material of the bonding wire 50 was aluminum. The width (diameter) of the bonding wire 50 was 400 μm.

A power cycle test was performed on the thus-produced power semiconductor module to measure a power cycle life (time to failure). The temperature (Tc) of the case of the power semiconductor module was set at 75° C.

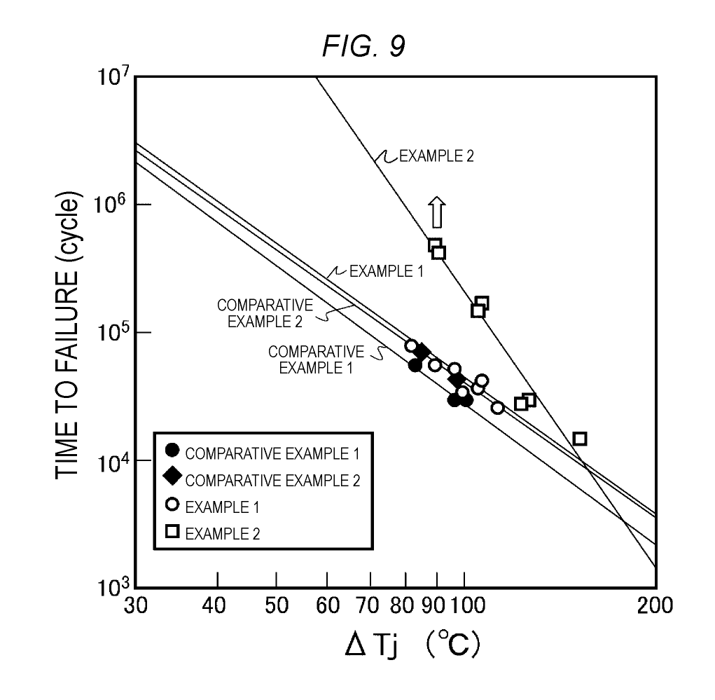

FIG. 9 is a diagram showing the results of measurement in the Examples. The results of the measurement of power cycle life in Example 1 are shown in FIG. 9. The abscissa axis represents the difference (ΔTj) between the junction temperature (Tj) during on-operation of the device and the junction temperature (Tj) during off-operation of the device, i.e. the difference between the junction temperature (Tj) during on-operation of the device and the case temperature (Tc) during off-operation of the device. The ordinate axis represents time to failure (cycles to failure).

### Example 2

A power semiconductor module having the same structure as the second embodiment was produced. A bonding wire 50 having a copper core layer 51 and an aluminum cover layer 52 was used. The power semiconductor module was produced in the same conditions as in Example 1 except for the bonding wire 50. The width (diameter) of the bonding wire 50 was 400 μm. The width (diameter) of the core layer 51 was 300 μm, and the thickness of the cover layer 52 was 50 μm.

A power cycle test was performed in the same conditions as in Example 1 to measure a power cycle life (time to failure). The results of the measurement of power cycle life in Example 2 are shown in FIG. 9.

### Comparative Example 1

A power semiconductor module was produced in the same conditions as in Example 1 except that the electrode pad consisted of a single layer of an aluminum film having a thickness of 4 μm, i.e. except that the electrode pad was devoid of the OPM layer 201 and the barrier metal layer 203.

A power cycle test was performed in the same conditions as in Example 1 to measure a power cycle life (time to failure). The results of the measurement of power cycle life in Comparative Example 1 are shown in FIG. 9.

### Comparative Example 2

A power semiconductor module was produced in the same conditions as in Example 2 except that the electrode pad consisted of a single layer of an aluminum film having a thickness of 4 μm, i.e. except that the electrode pad was devoid of the OPM layer 201 and the barrier metal layer 203.

A power cycle test was performed in the same conditions as in Example 1 to measure a power cycle life (time to failure). The results of the measurement of power cycle life in Comparative Example 2 are shown in FIG. 9.

The time to failure of Example 1 was found to be 1.5 times that of Comparative Example 1 at ΔTj=100° C., and 1.3 times at ΔTj=75° C. The data thus verifies that in the case of using aluminum for the bonding layer 50, the provision of the OPM layer 201 enhances the reliability.

The time to failure of Example 2 was found to be 4.7 times that of Comparative Example 2 at ΔTj=100° C., and 15 times at ΔTj=75° C. The data thus verifies that in the case of using the bonding layer 50 having the copper core layer 51 and the aluminum cover layer 52, the provision of the OPM layer 201 enhances the reliability. No failure had occurred in the power semiconductor module of Example 2 at ΔTj=90° C. (see the data under the arrow in FIG. 9); it is expected that the actual time to failure will be longer.

The time to failure of Comparative Example 2, which uses the bonding wire 50 having the copper core layer 51 and the aluminum cover layer 52, was found to be 1.5 times that of Comparative Example 1 at ΔTj=100° C., and 1.3 times at ΔTj=75° C. On the other hand, the time to failure of Example 2 was found to be 7.1 times that of Comparative Example 1 at ΔTj=100° C., and 19 times at ΔTj=75° C. The comparative data indicates the significant improvement achieved by Example 2.

The measurement results thus demonstrate that the combination of the bonding wire 50, having the copper core layer 51 and the aluminum cover layer 52, with the OPM layer 201 can achieve significant enhancement of the reliability.

While the first to fourth embodiments have been described in terms of SBD as a semiconductor chip, it is possible to use other types of semiconductor chips such as MOSFET (Metal Oxide Semiconductor Field Effect Transistor), IGBT (Insulated Gate Bipolar Transistor), and a diode other than SBD.

While the second to fourth embodiments have been described with reference to the case of providing the pad layer 202 and the barrier metal layer 203, which are each made of a material different from the material of the OPM layer 201, it is possible to employ a structure which is devoid of the pad layer 202 and the barrier metal layer 203 and in which the OPM layer 201 is in contact with the semiconductor layer 100.

While the manufacturing method for the power semiconductor module of the first embodiment has been described with reference to the case of forming the OPM layer 201 after the cutting of a semiconductor wafer, it is possible to form the OPM layer 201 before the cutting of the semiconductor wafer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer;
an electrode provided on the semiconductor layer; and
a bonding wire connected to the electrode, wherein
the electrode comprises a first metal layer containing copper, a second metal layer containing aluminum and between the first metal layer and the semiconductor layer, and a third metal layer between the first metal layer and the second metal layer, the third metal layer comprising a material different from those of the first metal layer and the second metal layer, and
the thickness of the first metal layer is greater than the thickness of the second metal layer and greater than the thickness of the third metal layer.

2. The semiconductor device according to claim 1, wherein the third metal layer contains at least one metal element selected from the group consisting of titanium, tungsten, and tantalum.

3. The semiconductor device according to claim 1, wherein the third metal layer contains at least one material selected from the group consisting of titanium, tungsten, tantalum, titanium nitride, tungsten nitride, tantalum nitride, and a titanium/tungsten alloy.

4. The semiconductor device according to claim 1, wherein the thickness of the first metal layer is between 20 μm and 300 μm.

5. The semiconductor device according to claim 1, wherein the bonding wire contains copper.

6. The semiconductor device according to claim 1, wherein the bonding wire has a core layer containing copper, and a cover layer covering the core layer.

7. The semiconductor device according to claim 6, wherein the cover layer contains at least one element selected from the group consisting of aluminum, silver, gold, and palladium.

8. The semiconductor device according to claim 1, wherein the width of the bonding wire is between 100 μm and 600 μm.

9. A semiconductor device, comprising:
a semiconductor layer;
an electrode on the semiconductor layer, the electrode comprising:
a first metal layer containing copper; and
a bonding wire connected to the electrode, the bonding wire comprising a core layer containing copper, and a cover layer covering the core layer.

10. The semiconductor device according to claim 9, wherein
the electrode further comprises a second metal layer containing aluminum and between the first metal layer and the semiconductor layer, and
the thickness of the first metal layer is greater than the thickness of the second metal layer.

11. The semiconductor device according to claim 10, wherein
the electrode further comprises a third metal layer between the first metal layer and the second metal layer, the third metal layer comprising a material different from that of the first metal layer and that of the second metal layer, and
the thickness of the first metal layer is greater than the thickness of the third metal layer.

12. The semiconductor device according to claim 9, wherein the thickness of the first metal layer is between 20 μm 300 μm.

13. The semiconductor device according to claim 9, wherein the cover layer contains at least one metal element selected from the group consisting of aluminum, silver, gold, and palladium.

14. The semiconductor device according to claim 9, wherein the first metal layer and the core layer are in contact with each other.

15. The semiconductor device according to claim 9, wherein
the electrode has a fourth metal layer, which is made of the same material as the cover layer, between the first metal layer and the bonding wire, and
the cover layer and the fourth metal layer are in contact with each other.

16. The semiconductor device according to claim 9, wherein the width of the bonding wire is between 100 μm and 600 μm.

17. A method for manufacturing a semiconductor device, comprising:
forming a first metal layer containing copper over a semiconductor layer from an ionized metal plasma; and
connecting a bonding wire to the first metal layer.

18. The method for manufacturing a semiconductor device according to claim 17, wherein
a second metal layer containing aluminum is formed on the semiconductor layer before forming the first metal layer,
a semiconductor chip including the semiconductor layer and the second metal layer is formed by cutting a semiconductor substrate after the forming of the second metal layer thereon, and
the first metal layer is then formed on the second metal layer.

19. The method for manufacturing a semiconductor device according to claim 18, wherein a third metal layer, comprising a material different from those of the first metal layer and the second metal layer, is formed on the second metal layer before the forming of the first metal layer.

20. The method for manufacturing a semiconductor device according to claim 17, wherein
the bonding wire comprises a core layer containing copper and a cover layer covering the core layer,
part of the cover layer is removed to expose the core layer before connecting the bonding wire onto the first metal layer, and
the exposed core layer is brought into contact with the first metal layer when connecting the bonding wire onto the first metal layer.
